(19) United States
(12) Patent Application Publication
(10) Pub. No.: US 2026/0169299 A1
(43) Pub. Date: Jun. 18, 2026

(54) ELECTRONIC DEVICE

(71) Applicant: Semiconductor Energy Laboratory Co., Ltd., Atsugi-shi, Kanagawa-ken (JP)

(72) Inventors: Akio ENDO, Atsugi (JP); Naoto KUSUMOTO, Isehara (JP)

(21) Appl. No.: 19/134,235

(22) PCT Filed: Dec. 8, 2023
(86) PCT No.: PCT/IB2023/062382

§ 371 Date: May 30, 2025

(30) Foreign Application Priority Data
Dec. 15, 2022 (JP) 2022-200144

(51) Int. Cl. G02B 27/01; H10K 59/10

(52) U.S. Cl. CPC G02B 27/0176; H10K 59/10; G02B 2027/0152; G02B 2027/0169; G02B 2027/0178

(57) ABSTRACT

An electronic device that can be easily attached and detached is provided. The electronic device is a goggles-type electronic device including a frame and a housing incorporating a display panel and an optical device. The frame can be worn on a head and includes a metal plate on the opposite side of a wearing surface. An electromagnet is provided on one surface of the housing. The electromagnet can attract the metal plate when energized, so that the housing can be fixed to the frame. With this structure, a user can easily attach and detach a portion functioning as the electronic device.

### TECHNICAL FIELD

One embodiment of the present invention relates to an electronic device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor device, a display apparatus, a liquid crystal display apparatus, a light-emitting apparatus, a lighting device, a power storage device, a memory device, an imaging capturing device, an operation method thereof, and a manufacturing method thereof.

Note that in this specification and the like, a semiconductor device generally means a device that can function by utilizing semiconductor characteristics. A transistor and a semiconductor circuit are embodiments of semiconductor devices. In addition, in some cases, a memory device, a display apparatus, an image capturing device, or an electronic device includes a semiconductor device.

### BACKGROUND ART

Goggles-type devices and glasses-type devices have been developed as electronic devices for virtual reality (VR), augmented reality (AR), and the like.

In addition, examples of a display apparatus that can be used for a display panel include, typically, a display apparatus including a liquid crystal element and a display apparatus including an organic EL (Electro Luminescence) element, a light-emitting diode (LED), or the like.

A display apparatus including an organic EL element does not need a backlight that is necessary for a liquid crystal display apparatus; thus, a thin, lightweight, high-contrast, and low-power display apparatus can be achieved. Patent Document 1, for example, discloses an example of a display apparatus using an organic EL element.

### REFERENCE

### Patent Document

[Patent Document 1] Japanese Published Patent Application No. 2018-107444

### SUMMARY OF THE INVENTION

### Problems to be Solved by the Invention

Electronic devices used for VR, AR, and the like are a kind of wearable device, which is preferably thin and lightweight in order to have improved portability and wearability.

On the other hand, there is a limit on reduction in weight of a display panel, an optical device, a controller, a battery, a housing where they are held, and the like, and a user feels some weight on his/her head. Therefore, the user is fatigued by long-term use in some cases. In addition, there has been a problem in that the attachment and detachment of the electronic device to and from the head are troublesome.

Thus, such an electronic device is desired to make a user feel less weight and to be easily attached and detached.

Thus, an object of one embodiment of the present invention is to provide an electronic device that is easily attached and detached. Another object is to provide an electronic device that makes a user feel less weight. Another object is to provide a novel electronic device.

Note that the description of these objects does not preclude the existence of other objects. One embodiment of the present invention does not necessarily achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention relates to an electronic device that is easily attached and detached.

One embodiment of the present invention is a goggles-type electronic device including a frame and a housing. The housing includes a display panel and an optical device inside. The housing includes an electromagnet on a first surface. The frame includes a metal plate on an opposite side of a surface worn on a head. The electromagnet attracts the metal plate to fix the first surface of the housing and the metal plate so as to face each other.

The metal plate includes a projected portion on a surface side. The housing includes a depressed portion on the first surface. Alignment can be performed by matching the projected portion and the depressed portion.

The metal plate can have a convex surface on the surface side, and the first surface of the housing can have a concave surface.

A surface of the metal plate and the first surface of the housing can each have a flat surface.

An assisting tool may be connected to the housing. The assisting tool is preferably composed of one or more selected from a multi-joint arm, a slide mechanism, and a balancer.

The display panel preferably includes an organic EL element. The optical device preferably includes a half mirror, a lens, a retardation plate, and a reflective polarizing plate.

### Effect of the Invention

According to one embodiment of the present invention, an electronic device that is easily attached and detached to and from a head can be provided. Alternatively, an electronic device that makes a user to feel less weight can be provided. Alternatively, a novel electronic device can be provided.

Note that the description of these effects does not preclude the existence of other effects. One embodiment of the present invention does not necessarily have all of these effects.

Other effects can be derived from the description of the specification, the drawings, and the claims.

### BRIEF DESCRIPTION OF THE DRAWINGS

FIG. 1A and FIG. 1B are diagrams illustrating an electronic device.

FIG. 2A and FIG. 2B are diagrams illustrating an electronic device.

FIG. 3A and FIG. 3B are diagrams illustrating an electronic device.

FIG. 4A is a diagram illustrating an assisting tool connected to an electronic device. FIG. 4B1 to FIG. 4B5 are diagrams illustrating operation of the assisting tool.

FIG. 5A and FIG. 5B are diagrams each illustrating an assisting tool connected to an electronic device.

FIG. 6A and FIG. 6B are diagrams illustrating an optical unit.

FIG. 7A to FIG. 7C are diagrams illustrating structure examples of a display panel.

FIG. 8A to FIG. 8C are diagrams illustrating a structure example of a display panel.

FIG. 9A and FIG. 9B are diagrams illustrating structure examples of a display panel.

FIG. 10A to FIG. 10F are diagrams illustrating structure examples of pixels.

FIG. 11A and FIG. 11B are diagrams illustrating a structure example of a display panel.

FIG. 12 is a diagram illustrating a structure example of a display panel.

FIG. 13 is a diagram illustrating a structure example of a display panel.

FIG. 14 is a diagram illustrating a structure example of a display panel.

FIG. 15 is a diagram illustrating a structure example of a display panel.

FIG. 16 is a diagram illustrating a structure example of a display panel.

FIG. 17 is a diagram illustrating a structure example of a display panel.

FIG. 18A and FIG. 18B are diagrams illustrating a vertical transistor.

FIG. 19A and FIG. 19B are diagrams illustrating a vertical transistor.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

In addition, even in the case where a single component is illustrated in a circuit diagram, the component may be composed of a plurality of parts as long as there is no functional inconvenience. For example, in some cases, a plurality of transistors that operate as a switch are connected in series or in parallel. Furthermore, in some cases, capacitors are separately arranged in a plurality of positions.

In addition, one conductor has a plurality of functions of a wiring, an electrode, a terminal, and the like in some cases; in this specification, a plurality of names are sometimes used for one component. Even in the case where components are illustrated in a circuit diagram as if they were directly connected to each other, the components may actually be connected to each other through one or more conductors; in this specification, even such a structure is included in the category of direct connection.

### Embodiment 1

In this embodiment, electronic devices of one embodiment of the present invention will be described.

One embodiment of the present invention is a goggles-type electronic device. The electronic device includes a frame and a housing incorporating a display panel and an optical device.

The frame can be worn on a head (face) and includes a metal plate on the opposite side of a wearing surface. An electromagnet is provided on one surface of the housing. When the electromagnet is energized, the metal plate can be attracted and the housing can be fixed to the frame.

With such a structure, the user can attach the housing to the frame as necessary while wearing the frame on his/her head. When not needed, only the housing can be detached from the frame. That is, a portion functioning as the electronic device can be easily attached and detached.

In addition, an assisting tool can be connected to the housing. Note that the assisting tool is a tool that assists a person's movement such as lifting of a heavy object to reduce a physical load. The user can wear the frame on his/her head and attach the housing connected to the assisting tool to the frame as necessary. Such a structure can reduce the weight of the housing that the user feels, thereby reducing the user's fatigue.

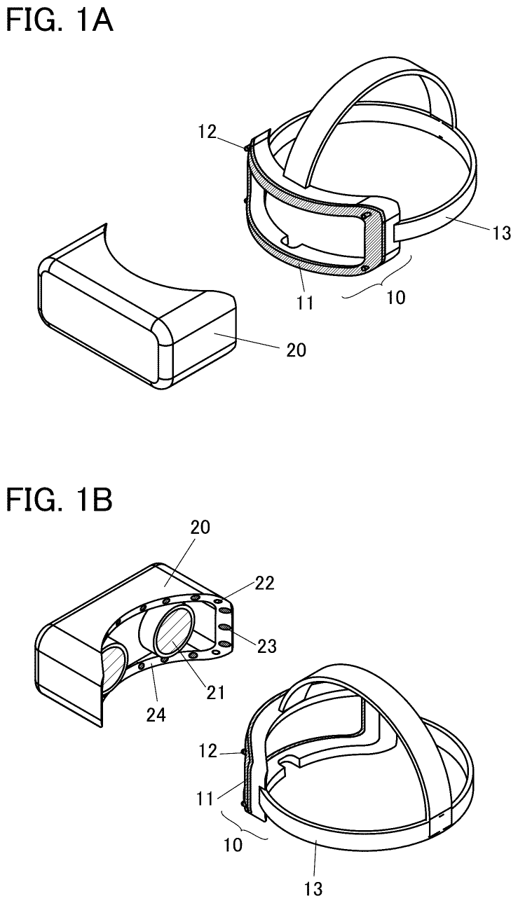

FIG. 1A and FIG. 1B are perspective views illustrating a goggles-type electronic device of one embodiment of the present invention. The electronic device includes a frame 10 worn on a head and a housing 20 incorporating components playing a role in displaying an image, for example, and has a structure where the frame 10 and the housing 20 can be separated from each other.

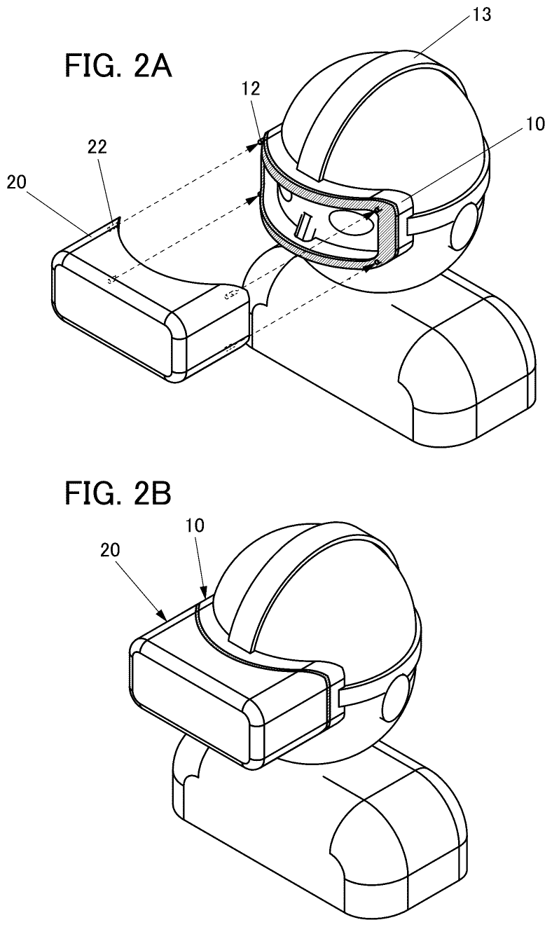

As illustrated in FIG. 2A, the frame 10 can be worn on a human head with a holding tool 13. Note that the holding tool 13 with a band-like shape illustrated in FIG. 2A is an example, and the frame 10 may be worn on a head with an ear-mounted or hat-type holding tool, for example.

The frame 10 has a concave surface on the wearing surface side so as to be easily worn on a human head, and has an opening portion in a region positioned in front of the eye when worn on the head. The frame 10 can also be regarded as having a hollow shape. A lightweight resin or the like is preferably used as a material on the wearing surface side of the frame 10, and a portion in contact with the face may be formed using an elastic material.

On the opposite side of the wearing surface of the frame 10, a metal plate 11 having ferromagneticity (e.g., iron, nickel, cobalt, or an alloy containing one or more of them) is provided. Although FIG. 1A illustrates an example where the frame-shaped metal plate 11 is provided, a plurality of small metal plates 11 may be provided.

The surface side of the metal plate 11 and the opposite side of the wearing surface side of the frame 10 each preferably have a convex surface. Such a shape allows the frame 10 to be thin and a wide field of view to be ensured.

A display panel (not illustrated), an optical device 21, and the like are incorporated in the housing 20. A first surface 24 of the housing 20 has a concave surface along the shape on the surface side of the metal plate 11, and an electromagnet 23 is provided on the first surface 24. The number of the electromagnets 23 is adjusted as necessary. The surface shape of the electromagnet 23 is not limited to a circular shape and an elliptical shape, and may be a polygonal shape.

When the electromagnet 23 is energized while the first surface 24 of the housing 20 is close to the metal plate 11, the electromagnet 23 can attract the metal plate 11. In this manner, the first surface 24 of the housing and the metal plate 11 can be fixed to face each other, as illustrated in FIG. 2B. That is, the housing 20 can be fixed to the frame 10.

Note that the housing 20 is a mode in which a battery is easily incorporated and thus the electromagnet 23 is preferably provided in the housing 20; however, in the case where a battery can be incorporated in the frame 10, the electromagnet 23 may be provided in the frame 10 and the metal plate 11 may be provided on the housing 20.

Note that in the case where the housing 20 is lightweight and does not require strong magnetic force, a permanent magnet can be used instead of the electromagnet. Alternatively, both an electromagnetic magnet and a permanent magnet may be used. Alternatively, a male-type joint can be used on one of the frame 10 side and the housing 20 side, and a female-type joint can be used on the other.

On the surface side of the metal plate 11, a projected portion 12 having a pin shape, a hemispherical shape, a conical shape, or the like is preferably provided. On the first surface 24 of the housing 20, a depressed portion 22 where the projected portion 12 can be inserted or overlapped so as to match is preferably provided. Matching the projected portion 12 and the depression portion 22 as indicated by dashed arrows in FIG. 2A enables easy alignment even in a state where the frame 10 cannot be seen directly.

Note that the projected portion 12 may be part of the metal plate 11 or fixed to the metal plate 11. Alternatively, the projected portion 12 may be provided on the opposite side of the wearing surface of the frame 10, and an opening portion through which the projected portion 12 penetrates may be provided in the metal plate 11.

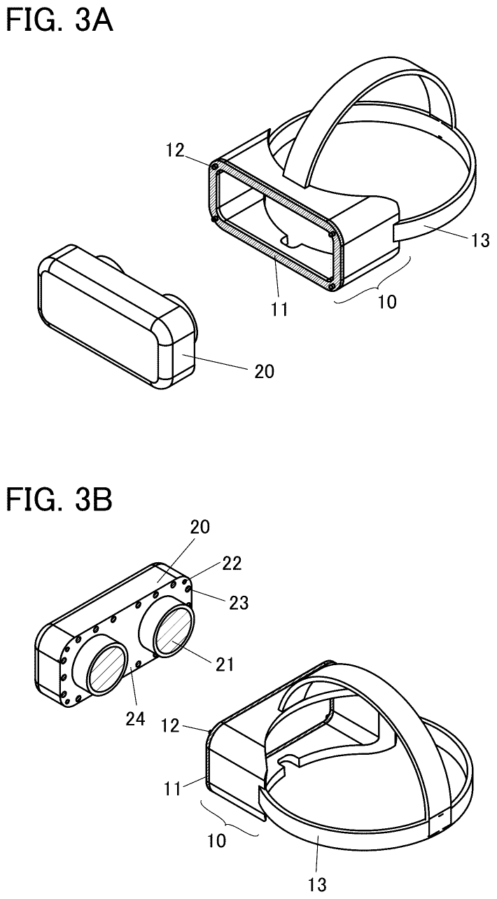

Note that as illustrated in FIG. 3A and FIG. 3B, the shape of the opposite side of the wearing surface of the frame 10, the surface of the metal plate 11, and the first surface 24 of the housing 20 may each be flat. In such a structure, the thickness of the frame 10 is larger than that in the structure illustrated in FIG. 1A and FIG. 1B, whereas the housing 20 can be small. Furthermore, the surface where the metal plate 11 and the housing 20 are in contact with each other is flat, which makes the above-described alignment of the projected portion 12 and the depressed portion 22 easy and accordingly facilitates attachment.

With the structure where the frame 10 and the housing 20 are separative as illustrated in FIG. 1A, FIG. 1B, FIG. 3A, and FIG. 3B, the relatively heavy housing 20 and the lightweight frame 10 can be attached and detached separately. This allows constant wearing of the lightweight frame 10 and appropriate attachment of the housing 20, thereby eliminating troublesomeness at the time of wearing and removing. Moreover, only the relatively heavy housing 20 can be easily detached, so that the user's fatigue can also be reduced.

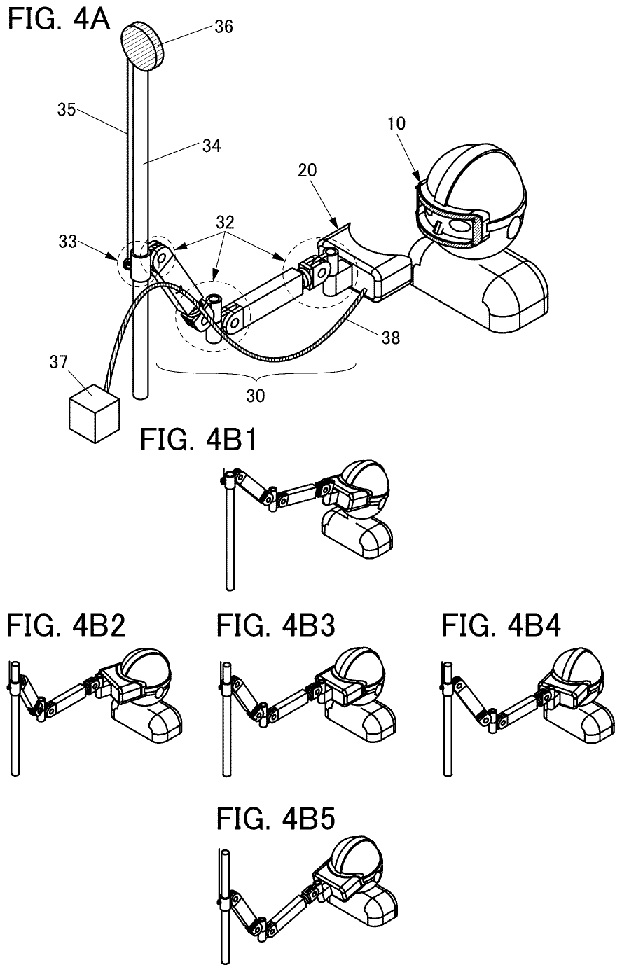

An assisting tool may be connected to the housing 20. FIG. 4A is a diagram illustrating an example where an assisting tool is connected to the housing 20. FIG. 4A illustrates an example of an assisting tool with a structure combining a multi-joint arm 30, a slide mechanism including a bush 33 (a cylindrical slide portion provided with a bearing on its inner surface) and a shaft 34, and a balancer 36.

Note that a balancer is a tool that makes the weight of a suspended object close to zero by balancing with the object utilizing tension of a spring or the like so as to move the object up and down with a small force.

The multi-joint arm 30 includes a plurality of pivots 32 so as to be bent or rotated to follow and support the housing 20 moved in various directions. Note that the multi-joint arm 30 illustrated in FIG. 4A is an example, and may be a multi-joint arm including more pivots. Alternatively, the multi-joint arm may include a pivot with which the moving direction is limited to only one direction (a vertical direction or a horizontal direction) or two directions (a vertical direction and a horizontal direction). The multi-joint arm may include a spring, an elastic arm, or the like.

The slide mechanism includes the bush 33 fitted on the metal shaft 34 with a smooth surface, and the bush 33 can be moved linearly. When the slide mechanism is connected to the multi-joint arm 30, the resistance when the housing 20 is moved up and down can be reduced as compared with the case where only the multi-joint arm 30 is used. Note that a structure without the slide mechanism can be employed.

Although the resistance is reduced by the slide mechanism, the weight of the multi-joint arm 30 is applied to the housing; thus, the weight that the user feels is preferably reduced by the balancer 36. For example, the spring-type balancer 36 is provided at an upper portion of the shaft 34, and the bush 33 and the balancer 36 are connected to each other with a wire 35. With such a structure, the weight at the time of moving the bush 33 connected to the multi-joint arm in the vertical direction can be reduced and the bush 33 can be fastened at a given position.

Note that in the case where the slide mechanism is not provided, the wire 35 may be connected to the housing 20 or the vicinity of a connection portion between the multi-joint arm 30 and the housing 20.

The housing 20 can be connected to a control unit 37 with a cable 38. The control unit 37 can supply video data, power, and the like to the housing 20 through the cable 38. Since the cable 38 can be connected to the housing 20 so as to be along the assisting tool, the user can move easily with almost no resistance of the cable 38. In addition, since video data and power can be supplied through the cable 38, a wireless device and a battery can be unnecessary and the weight of the whole housing portion can be reduced.

Such a use of the assisting tool can reduce the weight of the whole housing even when the housing 20 is moved in various directions as illustrated in FIG. 4B1 to FIG. 4B5, thereby reducing the user's fatigue.

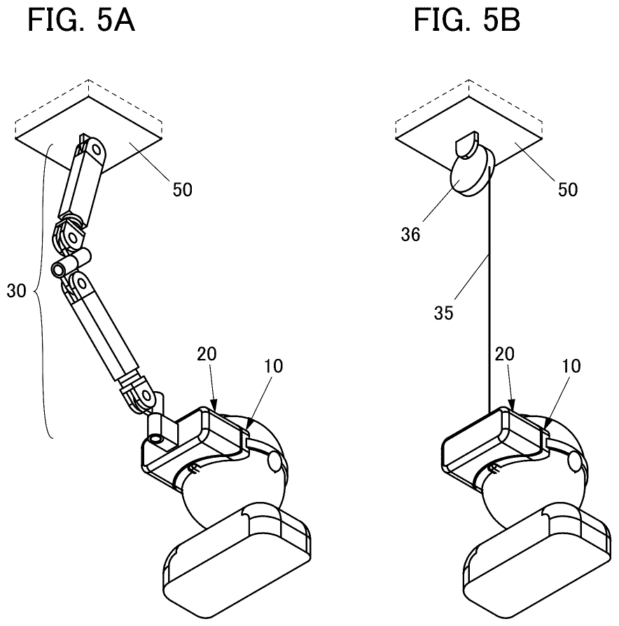

Note that the connection structure of the assisting tool and the housing 20 illustrated in FIG. 4A is an example; for example, the multi-joint arm 30 fixed to a ceiling 50 may be connected to the housing 20, as illustrated in FIG. 5A. Alternatively, the balancer 36 fixed to the ceiling 50 and the housing 20 may be connected to each other with the wire 35, as illustrated in FIG. 5B. Note that the multi-joint arm can also be fixed to a wall or a floor.

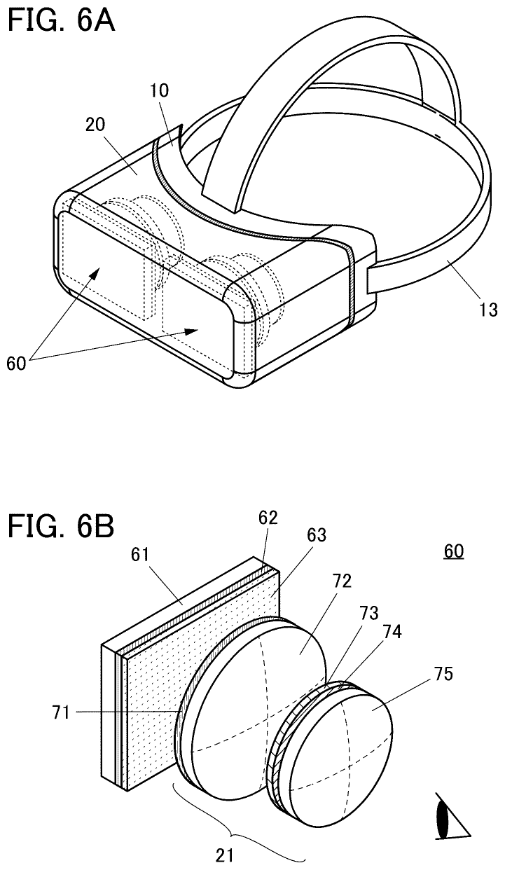

FIG. 6A is a diagram illustrating a display unit 60 incorporated in the housing 20. FIG. 6B is a diagram illustrating components of the display unit 60.

A user can see an image displayed on a display panel 61 when bringing the eyes near the optical device 21. The user sees the image while a viewing angle is widened by the optical device 21, and thus can obtain a sense of immersion and a realistic sensation.

A linear polarizing plate 62 and a retardation plate 63 can be attached to the display surface of the display panel 61.

The optical device 21 can include a half mirror 71, a lens 72, a retardation plate 73, a reflective polarizing plate 74, and a lens 75, for example. The optical device 21 is also referred to as a pancake lens in some cases because of its thin shape.

With such a structure, light emitted from the display panel 61 is converted into linearly polarized light or circularly polarized light to be utilized, whereby reflection and transmission can be selectively performed with a component placed on an optical path. Therefore, the optical path length can be secured in a limited space, and the focal length of the optical device can be shortened.

The two display units 60 are incorporated in the housing 20 so that surfaces of the lenses 75 are exposed on the inner side. One of the display units 60 is for a right eye, the other of the display units 60 is for a left eye, and each of the display units 60 displays an image using parallax, so that the image can be perceived as a three-dimensional image.

In addition, the housing 20, the frame 10, or the holding tool 13 may be provided with an input terminal and an output terminal. To the input terminal, a cable for supplying a video signal from a video output device or the like, electric power for charging a battery, and the like can be connected. The output terminal can function as, for example, an audio output terminal to which earphones, headphones, or the like can be connected. Note that in the case where audio data can be output by wireless communication or sound is output from an external video output device, the audio output terminal is not necessarily provided.

In addition, a wireless communication module, a memory module, and the like may be provided inside the housing 20, the frame 10, or the holding tool 13. Content to be watched can be downloaded via wireless communication using the wireless communication module and can be stored in the memory module. Accordingly, the user can watch the downloaded content offline.

In addition, a gaze sensor may be provided in the housing 20. For example, operation buttons for power-on, power-off, sleep, volume control, channel change, menu display, selection, decision, and back, and operation buttons for play, stop, pause, fast forward, and fast backward of moving images are displayed and the operation buttons are visually recognized, so that the respective operations can be performed. In addition, an operation button for energizing the electromagnet 23 may be displayed, and the housing 20 may be attached and detached by an operation using gaze sensing.

In addition, an optical sensor that senses a blink may be provided in the housing 20, and the above-described operations may be performed by a blinking operation. For example, the number of blinks within a certain period of time, a difference in eye-closing time, or the like can be assigned to the operation. A microphone may be provided in the housing 20 and the above-described operations may be performed by speech recognition.

By the above-described gaze sensing, blink detection, or speech recognition, the operation of the electronic device, attachment and detachment of the housing 20, and the like can be performed in a hygienic manner without a touch on the housing 20 with a finger or the like. That is, the electronic device of one embodiment of the present invention is also suitable for use in a construction site, a medical environment, or the like where the operation with a finger is sometimes difficult. Note that for grasping the ambient conditions, a camera may be connected to the housing 20 so that an image taken by the camera can be displayed using the display unit 60 in real time.

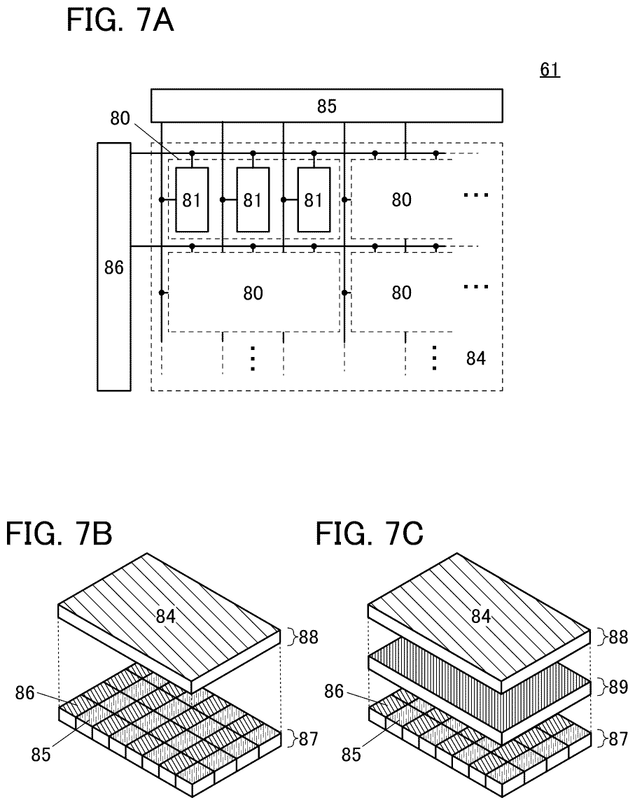

FIG. 7A is a diagram illustrating the display panel 61 illustrated in FIG. 6B. The display panel 61 includes a pixel array 84, a circuit 85, and a circuit 86. The pixel array 84 includes pixels 80 arranged in a column direction and a row direction.

The pixel 80 can include a plurality of subpixels 81. The subpixel 81 has a function of emitting light for display.

Note that in this specification, although the minimum unit in which an independent operation is performed in one “pixel” is defined as a “subpixel” in the description for convenience, a “pixel” may be replaced with a “region” and a “subpixel” may be replaced with a “pixel.”

The subpixel 81 includes a light-emitting device emitting visible light. An EL element such as an OLED (Organic Light Emitting Diode) or a QLED (Quantum-dot Light Emitting Diode) is preferably used as the light-emitting device. As a light-emitting substance contained in the EL element, a substance emitting fluorescent light (a fluorescent material), a substance emitting phosphorescent light (a phosphorescent material), a substance exhibiting thermally activated delayed fluorescence (a thermally activated delayed fluorescent (TADF) material), an inorganic compound (a quantum dot material or the like), and the like can be given. In addition, an LED (Light Emitting Diode) such as a micro LED can be also used as the light-emitting device.

The circuit 85 and the circuit 86 are driver circuits for driving the subpixel 81. The circuit 85 can have a function of a source driver circuit, and the circuit 86 can have a function of a gate driver circuit. A shift register circuit or the like can be used as each of the circuit 85 and the circuit 86, for example.

Note that as illustrated in FIG. 7B, a structure where the circuit 85 and the circuit 86 are provided in a layer 87, the pixel array 84 is provided in a layer 88, and the layer 87 and the layer 88 overlap with each other may be employed. This structure enables a display apparatus with a narrow bezel to be formed.

In addition, when the driver circuits are provided below the pixel array 84, the wiring length can be shortened and the wiring capacitance can be reduced. Accordingly, a display panel capable of a high-speed operation with low power consumption can be provided.

In addition, when each of the circuit 85 and the circuit 86 is divided and arranged as illustrated in FIG. 7B, part of the pixel array 84 can be driven. For example, part of image data in the pixel array 84 can be rewritten. Furthermore, part of the pixel array 84 can be operated at different operating frequency.

The layout and area of the circuit 85 and the circuit 86 illustrated in FIG. 7B are examples and can be changed as appropriate. In addition, part of each of the circuit 85 and the circuit 86 can be formed in the same layer as the pixel array 84. Furthermore, a circuit such as a memory circuit, an arithmetic circuit, or a communication circuit may be provided in the layer 87.

In this structure, for example, the layer 87 can be provided on a single crystal silicon substrate, the circuit 85 and the circuit 86 can be formed with transistors including silicon in channel formation regions (hereinafter Si transistors), and pixel circuits included in the pixel array 84 provided in the layer 88 can be formed with transistors including a metal oxide in channel formation regions (hereinafter OS transistors). An OS transistor can be formed with a thin film and can be formed to be stacked over a Si transistor.

Note that as illustrated in FIG. 7C, a structure where a layer 89 including OS transistors is provided between the layer 87 and the layer 88 may be employed. Some of the pixel circuits included in the pixel array 84 in the layer 89 can be provided with OS transistors. Alternatively, some of the circuit 85 and the circuit 86 can be provided with OS transistors. Alternatively, some of the circuits that can be provided in the layer 87, such as a memory circuit, an arithmetic circuit, and a communication circuit, can be provided with OS transistors.

At least part of this embodiment can be implemented in combination with the other embodiments and the example described in this specification as appropriate.

### Embodiment 2

In this embodiment, structure examples of a display panel that can be employed for the electronic device according to one embodiment of the present invention will be described. A display panel described below as an example can be employed for the display panel 61 in Embodiment 1.

One embodiment of the present invention is a display panel including light-emitting elements (also referred to as light-emitting devices). The display panel includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers including different light-emitting materials. For example, when three kinds of light-emitting elements that emit red (R), green (G), and blue (B) light are included, a full-color display panel can be achieved.

In the case of manufacturing a display panel including a plurality of light-emitting elements of different emission colors, at least layers (light-emitting layers) including light-emitting materials each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a formed film due to vapor scattering, for example; accordingly, it is difficult to achieve a high resolution and a high aperture ratio of the display panel. In addition, the outline of the layer might blur during evaporation, so that the thickness of an end portion might be reduced. That is, the thickness of an island-shaped light-emitting layer might vary from place to place. In addition, in the case of manufacturing a display panel with a large size, a high definition, or a high resolution, a manufacturing yield might be reduced because of low dimensional accuracy of the metal mask and deformation due to heat or the like. Thus, a measure has been taken for a pseudo increase in resolution (also referred to as pixel density) by employing unique pixel arrangement such as PenTile arrangement.

Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by a photolithography method without using a shadow mask such as a fine metal mask (an FMM). Accordingly, it is possible to achieve a display panel with a high resolution and a high aperture ratio, which has been difficult to achieve. Moreover, since the EL layers can be formed separately, it is possible to achieve a display panel that performs extremely clear display with high contrast and high display quality. Note that, fine patterning of the EL layers may be performed using both a metal mask and a photolithography method, for example.

In addition, part or the whole of the EL layer can be physically divided from each other. This can inhibit leakage current flowing between adjacent light-emitting elements through a layer (also referred to as a common layer) shared by the light-emitting elements. Thus, it is possible to prevent light emission due to unintended crosstalk, so that a display panel with extremely high contrast can be achieved. In particular, a display panel having high current efficiency at low luminance can be achieved.

Note that in one embodiment of the present invention, the display panel can be also obtained by combining a light-emitting element that emits the white light with a color filter. In that case, light-emitting elements having the same structure can be used as light-emitting elements provided in pixels (subpixels) that emit light of different colors, which allows all the layers to be common layers. In addition, part or the whole of the EL layer may be divided from each other in a step using a photolithography method. Thus, leakage current through the common layer is inhibited; accordingly, a high-contrast display panel can be achieved. In particular, when an element has a tandem structure where a plurality of light-emitting layers are stacked with a highly conductive intermediate layer therebetween, leakage current through the intermediate layer can be effectively prevented, so that a display panel with high luminance, high resolution, and high contrast can be achieved.

In the case where the EL layer is processed by a photolithography method, part of the light-emitting layer is sometimes exposed to cause degradation. Thus, an insulating layer covering at least the side surface of the island-shaped light-emitting layer is preferably provided. The insulating layer may cover part of the top surface of the island-shaped EL layer. For the insulating layer, a material having a barrier property against water and oxygen is preferably used. For example, an inorganic insulating film that is less likely to diffuse water or oxygen can be used. This can inhibit deterioration of the EL layer and can achieve a highly reliable display panel.

Moreover, between two adjacent light-emitting elements, there is a region (a concave portion) where none of the EL layers of the light-emitting elements is provided. In the case where a common electrode or a common electrode and a common layer are formed to cover the concave portion, a phenomenon where the common electrode is divided by a step at an end portion of the EL layer (such a phenomenon is also referred to as disconnection) might occur, which might cause insulation of the common electrode over the EL layer. In view of this, a local gap positioned between the two adjacent light-emitting elements is preferably filled with a resin layer (also referred to as local filling planarization, or LFP) functioning as a planarization film. The resin layer has a function of a planarization film. This structure can inhibit disconnection of the common layer or the common electrode and can achieve a highly reliable display panel.

More specific structure examples of the display panel according to one embodiment of the present invention will be described below with reference to drawings.

### [Structure Example 1]

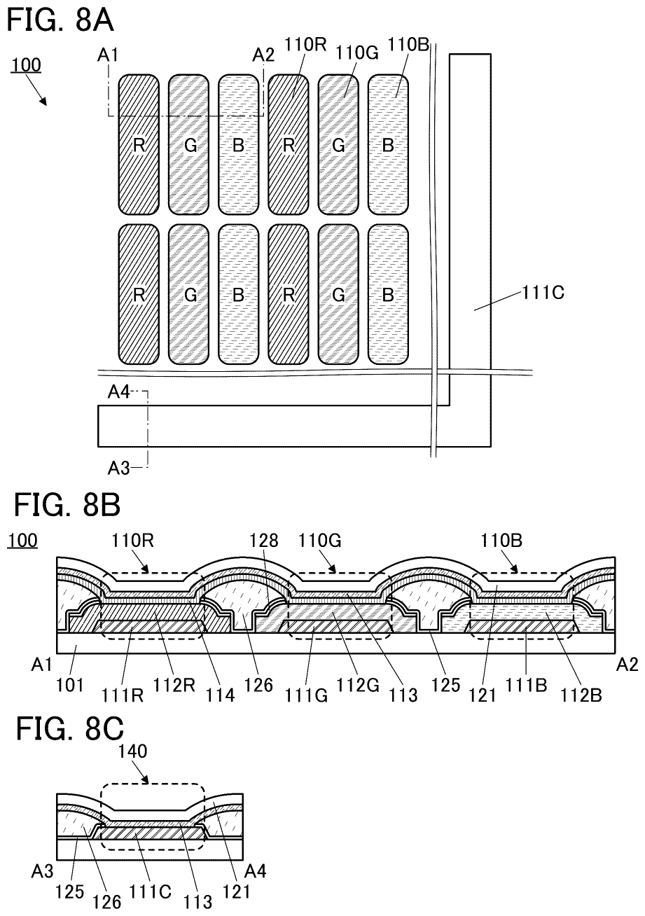

FIG. 8A is a schematic top view illustrating a display panel 100 according to one embodiment of the present invention. The display panel 100 includes, over a substrate 101, a plurality of light-emitting elements 110R exhibiting red, a plurality of light-emitting elements 110G exhibiting green, and a plurality of light-emitting elements 110B exhibiting blue. In FIG. 8A, light-emitting regions of the light-emitting elements are denoted by R, G, and B to easily differentiate the light-emitting elements.

The light-emitting elements 110R, the light-emitting elements 110G, and the light-emitting elements 110B are each arranged in a matrix. FIG. 8A illustrates what is called stripe arrangement, in which the light-emitting elements of the same color are arranged in one direction. Note that an arrangement method of the light-emitting elements is not limited thereto; an arrangement method such as S-stripe arrangement, delta arrangement, Bayer arrangement, or zigzag arrangement may be employed, or PenTile arrangement, diamond arrangement, or the like can be also used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As the light-emitting substance contained in the EL element, not only an organic compound but also an inorganic compound (a quantum dot material or the like) can be used.

FIG. 8A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or may be provided along two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like. Note that in this specification and the like, a top surface shape refers to a shape in a plan view, i.e., a shape seen from above.

FIG. 8B and FIG. 8C are schematic cross-sectional views corresponding to the dashed-dotted line A1-A2 and the dashed-dotted line A3-A4, respectively, in FIG. 8A. FIG. 8B is a schematic cross-sectional view illustrating the light-emitting element 110R, the light-emitting element 110G, and the light-emitting element 110B provided over the substrate 101, and FIG. 8C is a schematic cross-sectional view illustrating a connection portion 140 where the connection electrode 111C and the common electrode 113 are connected to each other. Note that the substrate 101 is provided with components of a pixel circuit that are connected to the pixel electrodes included in the light-emitting element 110R, the light-emitting element 110G, and the light-emitting element 110B.

The light-emitting element 110R includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can be also referred to as an EL layer and includes at least a layer containing a light-emitting substance (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

Each of the organic layer 112 and the common layer 114 can independently include one or more of an electron-injection layer, an electron-transport layer, a hole-injection layer, and a hole-transport layer. For example, it is possible to employ a structure where the organic layer 112 has a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a light-transmitting property with respect to visible light is used for either the pixel electrodes or the common electrode 113, and a conductive film having a reflective property is used for the other. When the pixel electrodes have light-transmitting properties and the common electrode 113 has a reflective property, a bottom-emission display panel can be obtained. In contrast, when the pixel electrodes have reflective properties and the common electrode 113 has a light-transmitting property, a top-emission display panel can be obtained. Note that when both the pixel electrodes and the common electrode 113 have light-transmitting properties, a dual-emission display panel can be obtained.

A protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the end portion of the pixel electrode 111 has a tapered shape, the organic layer 112 that is provided along the end portion of the pixel electrode 111 can also have a tapered shape. When the end portion of the pixel electrode 111 has a tapered shape, coverage with the organic layer 112 provided beyond the end portion of the pixel electrode 111 can be increased. Furthermore, when the side surface of the pixel electrode 111 has a tapered shape, a material (for example, also referred to as dust or particles) in a manufacturing step is easily removed by processing such as cleaning, which is preferable.

Note that in this specification and the like, a tapered shape indicates a shape in which at least part of a side surface of a component is inclined to a substrate surface. For example, a tapered shape preferably includes a region where an angle formed between the inclined side surface and the substrate surface (such an angle is also referred to as a taper angle) is less than 90°.

The organic layer 112 is processed into an island shape by a photolithography method. Thus, an angle formed between the top surface and the side surface of an end portion of the organic layer 112 is approximately 90°. In contrast, an organic film formed using an FMM (Fine Metal Mask) or the like tends to be gradually thinner in a portion closer to its end portion, and has a sloped top surface in the range greater than or equal to 1 μm and less than or equal to 10 μm, for example; thus, such a shape is difficult to distinguish the top surface and the side surface from each other.

An insulating layer 125, a resin layer 126, and a layer 128 are included between two adjacent light-emitting elements.

Between two adjacent light-emitting elements, the side surfaces of the organic layers 112 are provided to face each other with the resin layer 126 therebetween. The resin layer 126 is positioned between the two adjacent light-emitting elements and is provided to fill regions between end portions of the organic layers 112 and between the two organic layers 112. The resin layer 126 has a top surface with a smooth convex shape, and the common layer 114 and the common electrode 113 are provided to cover the top surface of the resin layer 126.

The resin layer 126 functions as a planarization film that fills a gap positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used as the photosensitive resin. As the photosensitive resin, a positive material or a negative material can be used.

The resin layer 126 may include a material absorbing visible light. For example, the resin layer 126 itself may be made of a material absorbing visible light, or the resin layer 126 may include a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surface of the organic layers 112. In addition, the insulating layer 125 is provided to cover an upper end portion of the organic layer 112. Furthermore, part of the insulating layer 125 is provided in contact with the top surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved in an organic solvent or the like used at the time of forming the resin layer 126. Therefore, the insulating layer 125 is provided between the organic layer 112 and the resin layer 126 to protect the side surfaces of the organic layer 112.

An insulating layer containing an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD (Atomic Layer Deposition) method is used for the insulating layer 125, the insulating layer 125 having few pinholes and an excellent function of protecting the EL layer can be formed.

Note that in this specification and the like, an oxynitride refers to a material that contains more oxygen than nitrogen in its composition, and a nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 125, a sputtering method, a CVD method, a PLD method, an ALD method, or the like can be used. The insulating layer 125 is preferably formed by an ALD method that offers good coverage.

In addition, a structure may be employed in which a reflective film (e.g., a metal film including one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has few pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, or a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure in which an organic insulating film is sandwiched between a pair of inorganic insulating films is preferable. Furthermore, it is preferable that the organic insulating film function as a planarization film. This enables the top surface of the organic insulating film to be flat, which results in improved coverage with the inorganic insulating film thereover and a higher barrier property. Moreover, the top surface of the protective layer 121 is flat, which is preferable because the influence of an uneven shape due to a lower structure can be reduced in the case where a component (e.g., a color filter, an electrode of a touch sensor, a lens array, or the like) is provided above the protective layer 121.

FIG. 8C illustrates the connection portion 140 where the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 8C illustrates the connection portion 140 where the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin; thus, problems do not arise in many cases even when the common layer 114 is positioned in the connection portion 140. Accordingly, the common electrode 113 and the common layer 114 can be formed using the same shielding mask, so that manufacturing cost can be reduced.

### [Structure Example 2]

A display panel whose structure is partly different from that of Structure Example 1 is described below. Note that the above description can be referred to for portions common to those in Structure Example 1, and the description is omitted in some cases.

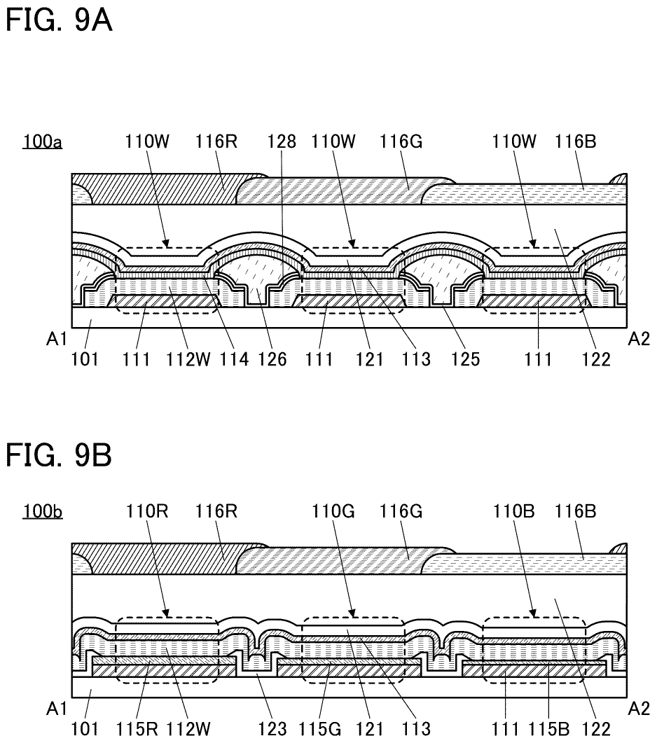

FIG. 9A is a schematic cross-sectional view of a display panel 100a. The display panel 100a is different from the display panel 100 mainly in the structure of the light-emitting element and including a coloring layer.

The display panel 100a includes light-emitting elements 110W that emit white light. The light-emitting elements 110W each include the pixel electrode 111, an organic layer 112W, the common layer 114, and the common electrode 113. The organic layer 112W emits white light. For example, the organic layer 112W can include two or more kinds of light-emitting materials whose emission colors are complementary colors. For example, the organic layer 112W can include a light-emitting organic compound that emits red light, a light-emitting organic compound that emits green light, and a light-emitting organic compound that emits blue light. Alternatively, the organic layer 112W may include a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display panel can achieve high contrast and high color reproducibility.

An insulating layer 122 that functions as a planarization film is provided over the protective layer 121, and a coloring layer 116R, a coloring layer 116G, and a coloring layer 116B are provided over the insulating layer 122.

An organic resin film or an inorganic insulating film with a flat top surface can be used for the insulating layer 122. The insulating layer 122 serves as a formation surface on which the coloring layer 116R, the coloring layer 116G, and the coloring layer 116B are formed; thus, with the flat top surface of the insulating layer 122, the thickness of the coloring layer 116R or the like can be uniform and color purity can be increased. Note that when the thickness of the coloring layer 116R or the like is non-uniform, the amount of light absorption varies depending on a place in the coloring layer 116R, which might decrease the color purity.

### [Structure Example 3]

FIG. 9B is a schematic cross-sectional view illustrating a display panel 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film that reflects visible light is used for the pixel electrode 111 and a film having a property of reflecting and transmitting visible light is used for the common electrode 113, so that a micro resonator (microcavity) structure can be achieved. In that case, by adjusting the thicknesses of the conductive layer 115R, the conductive layer 115G, and the conductive layer 115B to obtain optimal optical path length, light with different wavelengths and increased intensities can be obtained from the light-emitting element 110R, the light-emitting element 110G, and the light-emitting element 110B even when the organic layer 112 that emits white light is used.

Furthermore, the coloring layer 116R, the coloring layer 116G, and the coloring layer 116B are provided on the optical paths of the light-emitting element 110R, the light-emitting element 110G, and the light-emitting element 110B, respectively, so that light with high color purity can be obtained.

In addition, an insulating layer 123 that covers end portions of the pixel electrode 111, the conductive layer 115R, the conductive layer 115G, and the conductive layer 115B is provided. An end portion of the insulating layer 123 preferably has a tapered shape. When the insulating layer 123 is provided, coverage with the organic layer 112W, the common electrode 113, the protective layer 121, and the like provided over the insulating layer 123 can be increased.

The organic layer 112W and the common electrode 113 are each provided as one continuous film shared by the light-emitting elements. Such a structure is preferable because the manufacturing process of the display panel can be greatly simplified.

Here, the end portion of the pixel electrode 111 preferably has a substantially vertical shape. Accordingly, a steep portion can be formed on the surface of the insulating layer 123, and thus a thin portion can be formed in part of the organic layer 112W that covers the steep portion or part of the organic layer 112W can be divided. Accordingly, generation of leakage current between adjacent light-emitting elements through the organic layer 112W can be inhibited without processing the organic layer 112W by a photolithography method or the like.

The above is the description of the structure example of the display panel.

### [Pixel Layout]

A pixel layout different from that in FIG. 8A will be mainly described below. There is no particular limitation on the arrangement of light-emitting elements (subpixels), and a variety of methods can be employed.

Examples of the top surface shape of the subpixel include polygons such as a triangle, a quadrangle (including a rectangle and a square), and a pentagon; polygons with rounded corners; an ellipse; and a circle. Here, the top surface shape of the subpixel corresponds to the top surface shape of a light-emitting region of the light-emitting element.

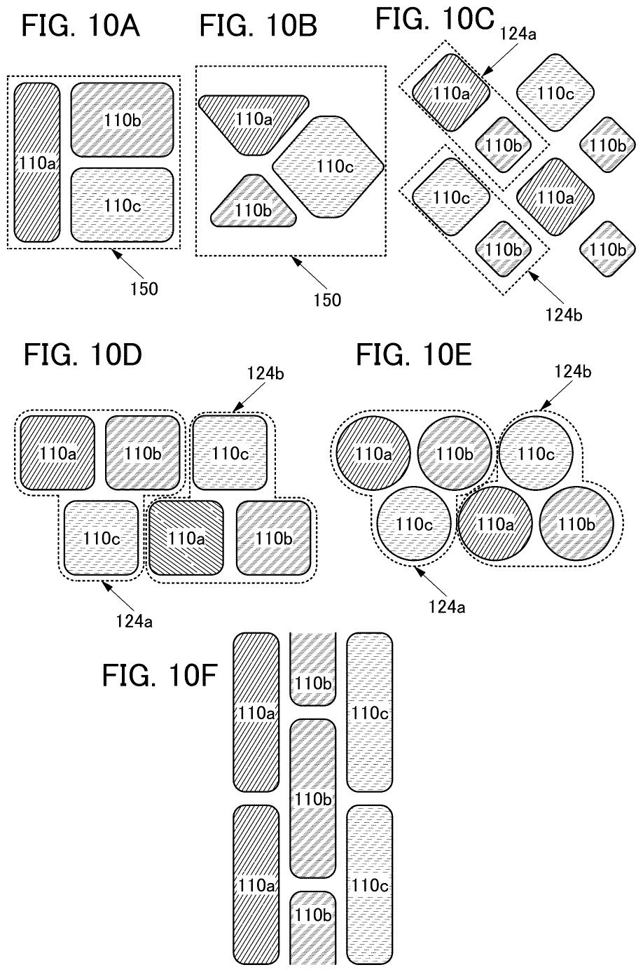

A pixel 150 illustrated in FIG. 10A employs S-stripe arrangement. The pixel 150 illustrated in FIG. 10A is composed of three subpixels: light-emitting elements 110a, 110b, and 110c. For example, the light-emitting element 110a may be a blue-light-emitting element, the light-emitting element 110b may be a red-light-emitting element, and the light-emitting element 110c may be a green-light-emitting element.

The pixel 150 illustrated in FIG. 10B includes the light-emitting element 110a whose top surface has a rough trapezoidal or rough triangle shape with rounded corners, the light-emitting element 110b whose top surface has a rough trapezoidal or rough triangle shape with rounded corners, and the light-emitting element 110c whose top surface has a rough tetragonal or rough hexagonal shape with rounded corners. In addition, the light-emitting element 110a has a larger light-emitting area than the light-emitting element 110b. In this manner, the shapes and sizes of the light-emitting elements can be independently determined. For example, the size of a light-emitting element with higher reliability can be made smaller. For example, the light-emitting element 110a may be a green-light-emitting element, the light-emitting element 110b may be a red-light-emitting element, and the light-emitting element 110c may be a blue-light-emitting element.

Pixels 124a and 124b illustrated in FIG. 10C employ PenTile arrangement. FIG. 10C illustrates an example where the pixels 124a each including the light-emitting element 110a and the light-emitting element 110b and the pixels 124b each including the light-emitting element 110b and the light-emitting element 110c are alternately arranged. For example, the light-emitting element 110a may be a red-light-emitting element, the light-emitting element 110b may be a green-light-emitting element, and the light-emitting element 110c may be a blue-light-emitting element.

The pixels 124a and 124b illustrated in FIG. 10D and FIG. 10E employ delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red-light-emitting element, the light-emitting element 110b may be a green-light-emitting element, and the light-emitting element 110c may be a blue-light-emitting element.

FIG. 10D illustrates an example where the top surface of each light-emitting element has a rough tetragonal shape with rounded corners, and FIG. 10E illustrates an example where the top surface of each light-emitting element has a circular shape.

FIG. 10F illustrates an example where light-emitting elements of different colors are arranged in a zigzag manner. Specifically, the positions of top sides of two light-emitting elements arranged in a column direction (e.g., the light-emitting element 110a and the light-emitting element 110b or the light-emitting element 110b and the light-emitting element 110c) are not aligned in a top view. For example, the light-emitting element 110a may be a red-light-emitting element, the light-emitting element 110b may be a green-light-emitting element, and the light-emitting element 110c may be a blue-light-emitting element.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Furthermore, in a method for manufacturing a display panel according to one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer has a polygonal shape with rounded corners, an elliptical shape, a circular shape, or the like in some cases. For example, when a resist mask with a square top surface is intended to be formed, a resist mask with a circular top surface may be formed, and the top surface of the EL layer may be circular.

To obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

At least part of this embodiment can be implemented in combination with the other embodiments and the example described in this specification as appropriate.

### Embodiment 3

In this embodiment, other structure examples of a display panel that can be employed for the electronic device according to one embodiment of the present invention will be described.

Display panels in this embodiment are high-resolution display panels, and particularly suitably used for display portions of wearable devices that can be worn on a head, such as VR devices like head-mounted displays and glasses-type AR devices.

### [Display Module]

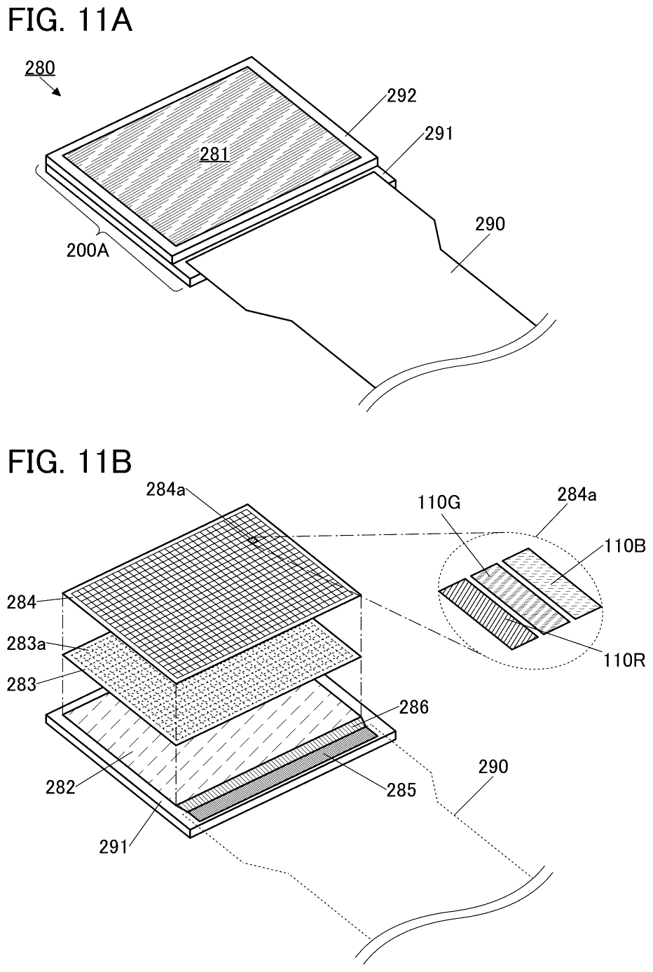

FIG. 11A is a perspective view of a display module 280. The display module 280 includes a display panel 200A and an FPC 290. Note that a display panel included in the display module 280 is not limited to the display panel 200A and may be any of a display panel 200B to a display panel 200F described later.

The display module 280 includes a substrate 291 and a substrate 292. The display module 280 includes a display portion 281. The display portion 281 is a region where an image is displayed.

FIG. 11B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 11B. The pixel 284a includes the light-emitting element 110R that emits red light, the light-emitting element 110G that emits green light, and the light-emitting element 110B that emits blue light.

The pixel circuit portion 283 includes a plurality of pixel circuits 283a arranged periodically. One pixel circuit 283a is a circuit for controlling light emission of three light-emitting devices included in one pixel 284a. One pixel circuit 283a may be provided with three circuits for controlling light emission of one light-emitting device. For example, the pixel circuit 283a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 282 includes a circuit for driving the pixel circuits 283a in the pixel circuit portion 283. r example, the circuit portion 282 preferably includes one or both of a gate line driver circuit and a source line driver circuit. The circuit portion 282 may further include at least one of an arithmetic circuit, a memory circuit, a power supply circuit, and the like. addition, a transistor provided in the circuit portion 282 may constitute part of the pixel circuit 283a. at is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. IC may be mounted on the FPC 290.

The display module 280 can have a structure where one or both of the pixel circuit portion 283 and the circuit portion 282 are provided to be stacked below the pixel portion 284; thus, the aperture ratio (effective display area ratio) of the display portion 281 can be significantly high. r example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have an extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as a head-mounted display or a glasses-type AR device. For example, even with a structure where the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic devices including a relatively small display portion. For example, the display module 280 can be suitably used for a display portion of a wearable electronic device such as a wristwatch.

### [Display Panel 200A]

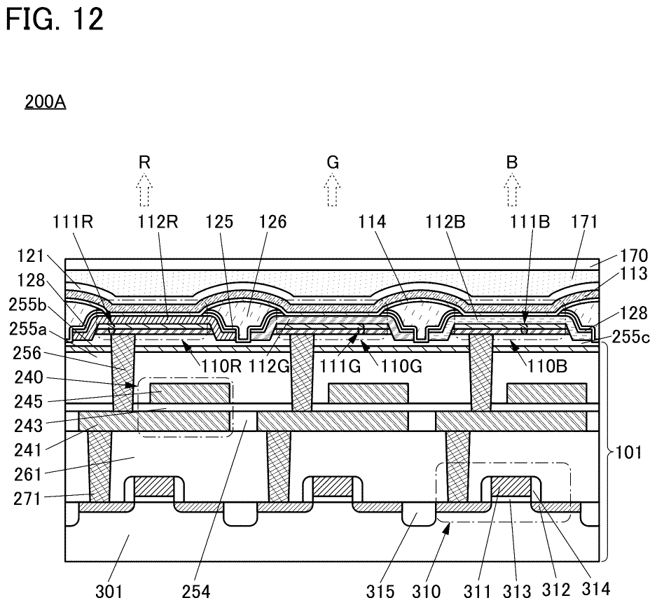

The display panel 200A illustrated in FIG. 12 includes a substrate 301, the light-emitting elements 110R, 110G, and 110B, a capacitor 240, and a transistor 310.

The substrate 301 corresponds to the substrate 291 in FIG. 11A and FIG. 11B.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and that a silicon nitride film be used for the insulating layer 255b. This enables the insulating layer 255b to function as an etching protective film. Although this embodiment describes an example where the insulating layer 255c is partly etched and a depressed portion is formed, the depressed portion is not necessarily provided in the insulating layer 255c.

The light-emitting element 110R, the light-emitting element 110G, and the light-emitting element 110B are provided over the insulating layer 255c. Embodiment 2 can be referred to for the structures of the light-emitting element 110R, the light-emitting element 110G, and the light-emitting element 110B.

Since the light-emitting devices for different emission colors are separately formed in the display panel 200A, the difference between the chromaticity at low luminance emission and that at high luminance emission is small. Furthermore, since the organic layers 112R, 112G, and 112B are apart from each other, generation of crosstalk between adjacent subpixels can be inhibited even when the display panel has a high resolution. It is thus possible to achieve a display panel that has a high resolution and high display quality.

In a region between adjacent light-emitting elements, the insulating layer 125, the resin layer 126, and the layer 128 are provided.

The pixel electrode 111R, the pixel electrode 111G, and the pixel electrode 111B of the light-emitting elements are each electrically connected to one of the source and the drain of the transistor 310 through a plug 256 that is embedded in the insulating layer 255a, the insulating layer 255b, and the insulating layer 255c, the conductive layer 241 that is embedded in the insulating layer 254, and the plug 271 that is embedded in the insulating layer 261. The top surface of the insulating layer 255c and the top surface of the plug 256 are level with or substantially level with each other. A variety of conductive materials can be used for the plugs.

In addition, the protective layer 121 is provided over the light-emitting elements 110R, 110G, and 110B. A substrate 170 is attached onto the protective layer 121 with an adhesive layer 171.

An insulating layer covering an end portion of the top surface of the pixel electrode 111 is not provided between two adjacent pixel electrodes 111. Thus, the distance between adjacent light-emitting elements can be extremely short. Accordingly, the display panel can have a high resolution or a high definition.

[Display Panel 200b]

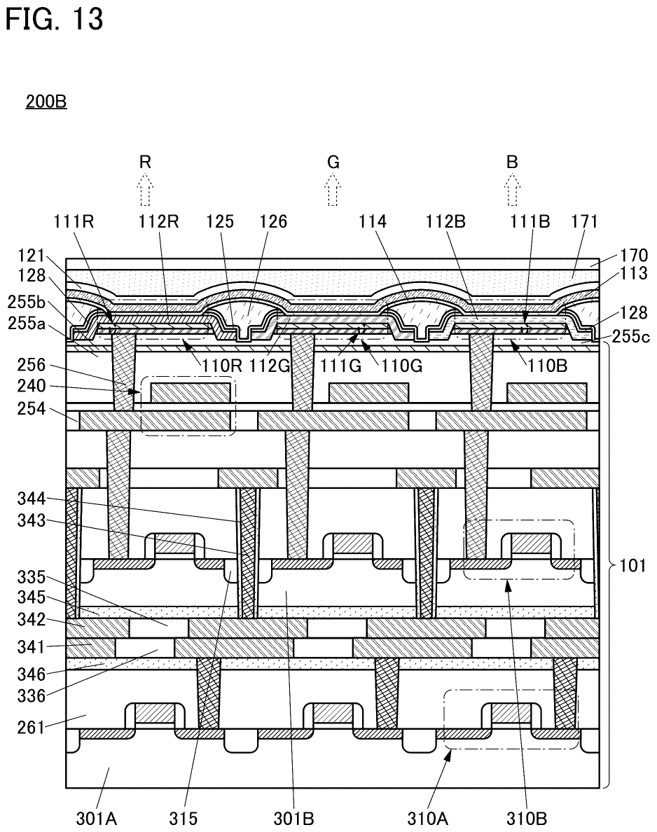

The display panel 200B illustrated in FIG. 13 has a structure where a transistor 310A and a transistor 310B in each of which a channel is formed in a semiconductor substrate are stacked. Note that in the following description of the display panel, the description of portions similar to those of the above display panel is omitted in some cases.

The display panel 200B has a structure where a substrate 301B provided with the transistor 310B, the capacitor 240, and the light-emitting devices is attached to a substrate 301A provided with the transistors 310A.

Here, an insulating layer 345 is provided on the bottom surface of the substrate 301B, and an insulating layer 346 is provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used for the protective layer 121 can be used.

The substrate 301B is provided with a plug 343 that penetrates the substrate 301B and the insulating layer 345. Here, an insulating layer 344 functioning as a protective layer is preferably provided to cover the side surface of the plug 343.

A conductive layer 342 is provided under the insulating layer 345 on the substrate 301B. The conductive layer 342 is embedded in an insulating layer 335, and the bottom surfaces of the conductive layer 342 and the insulating layer 335 are planarized. Furthermore, the conductive layer 342 is electrically connected to the plug 343.

A conductive layer 341 is provided over the insulating layer 346 over the substrate 301A. The conductive layer 341 is embedded in an insulating layer 336, and the top surfaces of the conductive layer 341 and the insulating layer 336 are planarized.

The same conductive material is preferably used for the conductive layer 341 and the conductive layer 342. A metal film containing an element selected from Al, Cr, Cu, Ta, Ti, Mo, and W, a metal nitride film containing the above element as a component (a titanium nitride film, a molybdenum nitride film, or a tungsten nitride film), or the like can be used, for example. Copper is particularly preferably used for the conductive layer 341 and the conductive layer 342. Accordingly, it is possible to employ a Cu-to-Cu (copper-to-copper) direct bonding technique (a technique for achieving electrical continuity by connecting Cu (copper) pads to each other).

[Display Panel 200c]

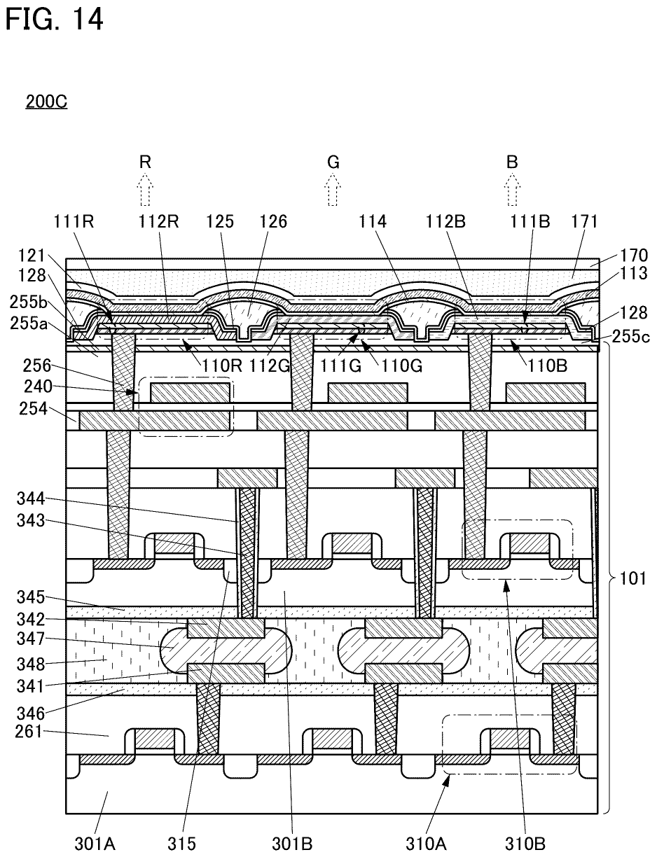

The display panel 200C illustrated in FIG. 14 has a structure where the conductive layer 341 and the conductive layer 342 are bonded to each other through a bump 347.

As illustrated in FIG. 14, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder is used for the bump 347 in some cases. In addition, an adhesive layer 348 may be provided between the insulating layer 345 and the insulating layer 346. Furthermore, in the case where the bump 347 is provided, a structure without the insulating layer 335 and the insulating layer 336 may be employed.

[Display Panel 200d]

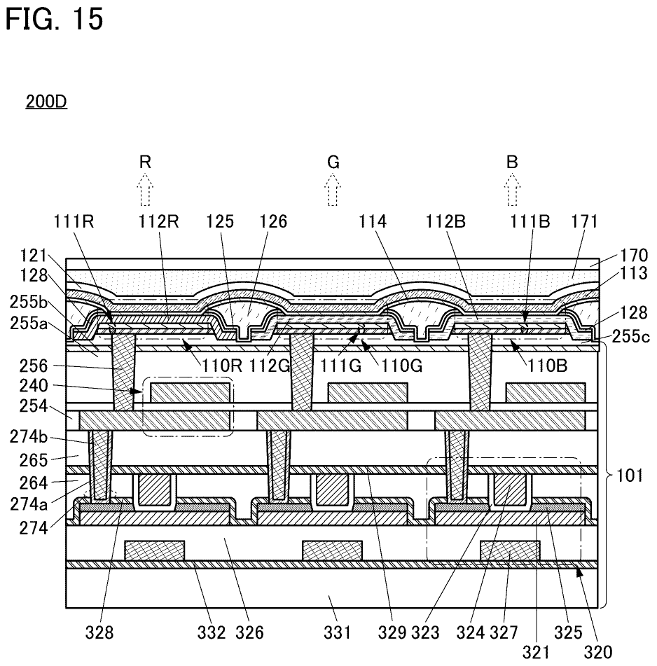

The display panel 200D illustrated in FIG. 15 differs from the display panel 200A mainly in a transistor structure.

A transistor 320 is a transistor (an OS transistor) in which a metal oxide (also referred to as an oxide semiconductor) is used for a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 11A and FIG. 11B.

The insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. For the insulating layer 332, for example, a film that is less likely to diffuse hydrogen or oxygen than a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film exhibiting semiconductor characteristics. The pair of conductive layers 325 is provided over and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. For the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with the top surface of the semiconductor layer 321 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are subjected to planarization treatment so that they are level with or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like into the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surfaces of openings in the insulating layer 265, the insulating layer 329, the insulating layer 264, and the insulating layer 328 and part of the top surface of the conductive layer 325, and a conductive layer 274b in contact with the top surface of the conductive layer 274a. In that case, a conductive material that is less likely to diffuse hydrogen and oxygen is preferably used for the conductive layer 274a.

Note that there is no particular limitation on the structures of the transistors included in the display panel of this embodiment. For example, a planar transistor, a staggered transistor, an inverted staggered transistor, or the like can be used. A top-gate transistor structure or a bottom-gate transistor structure may be employed. Gates may be provided above and below a semiconductor layer where a channel is formed.

A structure where the semiconductor layer where a channel is formed is interposed between two gates is employed for the transistor 320. The two gates may be connected to each other and supplied with the same signal to drive the transistor. Alternatively, a potential for controlling the threshold voltage may be supplied to one of the two gates and a potential for driving may be supplied to the other of the two gates to control the threshold voltage of the transistor.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The bandgap of a metal oxide used for the semiconductor layer of the transistor is preferably greater than or equal to 2 eV, further preferably greater than or equal to 2.5 eV. The use of a metal oxide having a wide bandgap can reduce the off-state current of the OS transistor.

A metal oxide preferably contains at least indium or zinc, and further preferably contains indium and zinc. A metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may contain silicon. Examples of silicon include amorphous silicon and crystalline silicon (low-temperature polysilicon, single crystal silicon, or the like).

Examples of the metal oxide that can be used for the semiconductor layer include indium oxide, gallium oxide, and zinc oxide. In addition, the metal oxide preferably contains two or three kinds selected from indium, the element M, and zinc. Note that the element Mis one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin.

Note that in the case where a metal oxide is used for the semiconductor layer, the metal oxide is preferably formed by a sputtering method or an ALD method. In the case where the metal oxide is formed by a sputtering method, the productivity can be increased and the film density can be increased. In the case where the metal oxide is formed by an ALD method, coverage with a film can be improved.

It is particularly preferable that an oxide containing indium, gallium, and zinc (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium, aluminum, and zinc (also referred to as IAZO). Alternatively, it is preferable to use an oxide containing indium, aluminum, gallium, and zinc (also referred to as IAGZO).

In the case where the metal oxide used for the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

In addition, it is particularly preferable to use gallium or tin as the element M. Note that a plurality of above elements may be used in combination as the element M. A metal oxide with In:M:Zn=40:1:10 or the neighborhood thereof is preferably used for the semiconductor layer. Specifically, a metal oxide with In:Sn:Zn=40:1:10 or the neighborhood thereof can be suitably used.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. In addition, when the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. Furthermore, when the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

Alternatively, the semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and provided over the first metal oxide layer can be suitably used. In particular, gallium or aluminum is preferably used as the element M.

Alternatively, a stacked-layer structure or the like of one selected from indium oxide, indium gallium oxide, and IGZO, and one selected from IAZO, IAGZO, and ITZO (registered trademark) may be used, for example.

As an oxide semiconductor having crystallinity, a CAAC (c-axis aligned crystalline)-OS, an nc (nanocrystalline)-OS, and the like can be given.

An OS transistor has much higher field-effect mobility than a transistor using amorphous silicon. In addition, the OS transistor has extremely low leakage current between a source and a drain in an off state (also referred to as off-state current), and charge accumulated in a capacitor that is connected in series with the transistor can be retained for a long period. Furthermore, the power consumption of the display panel can be reduced with the use of the OS transistor.

In addition, to increase the emission luminance of the light-emitting device included in the pixel circuit, the amount of current flowing through the light-emitting device needs to be increased. To increase the amount of current, the source-drain voltage of a driving transistor included in the pixel circuit needs to be increased. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

In addition, when transistors operate in a saturation region, a change in source-drain current relative to a change in gate-source voltage is smaller in an OS transistor than in a Si transistor. Accordingly, when an OS transistor is used as the driving transistor included in the pixel circuit, the amount of a current flowing between the source and the drain can be finely set by a change in gate-source voltage; thus, the amount of a current flowing through the light-emitting device can be controlled. Accordingly, the number of gray levels in the pixel circuit can be increased.

In addition, regarding saturation characteristics of current flowing when a transistor operates in a saturation region, even in the case where the source-drain voltage of an OS transistor gradually increases, more stable current (saturation current) can be fed through the OS transistor than through a Si transistor. Thus, with the use of an OS transistor as the driving transistor, stable current can be fed through the light-emitting device even when the current-voltage characteristics of EL devices vary, for example. In other words, when the OS transistor operates in the saturation region, the source-drain current hardly changes even with an increase in the source-drain voltage; thus, the emission luminance of the light-emitting device can be stable.

As described above, with the use of an OS transistor as the driving transistor included in the pixel circuit, it is possible to achieve “reduction in power consumption,” “increase in emission luminance,” “increase in the number of gray levels,” “inhibition of variation in light-emitting devices,” and the like.

### [Display Panel 200F]

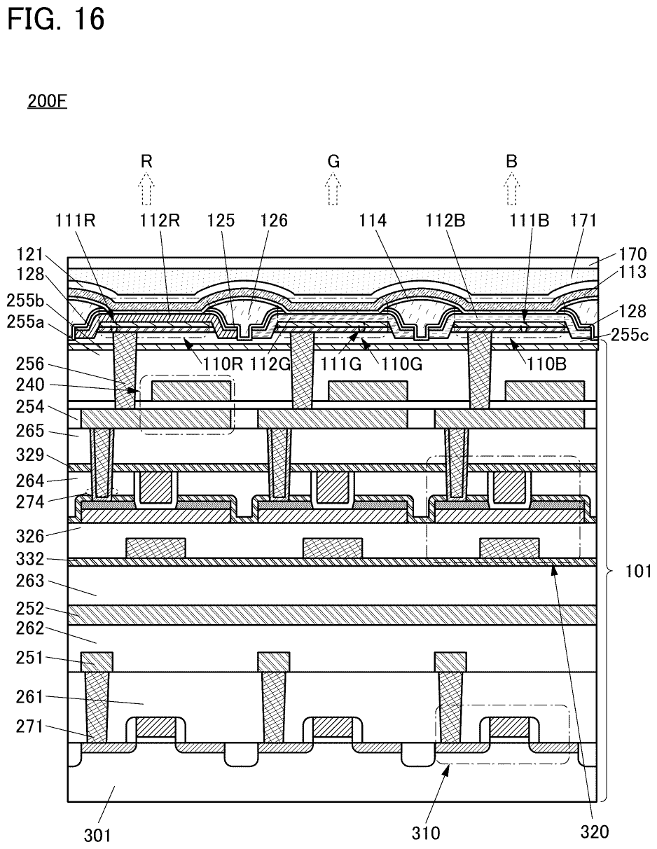

The display panel 200F illustrated in FIG. 16 has a structure where the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. Furthermore, an insulating layer 263 and the insulating layer 332 are provided to cover the conductive layer 252, and the transistor 320 is provided over the insulating layer 332. Moreover, the insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. In addition, the transistor 310 can be used as a transistor included in the pixel circuit or a transistor included in a driver circuit (a gate line driver circuit or a source line driver circuit) for driving the pixel circuit. Furthermore, the transistor 310 and the transistor 320 can be used as transistors included in a variety of circuits such as an arithmetic circuit or a memory circuit.

With such a structure, not only the pixel circuit but also the driver circuit and the like can be formed directly under the light-emitting devices; thus, the display panel can be downsized as compared with the case where the driver circuit is provided around a display region.

### [Display Panel 200G]

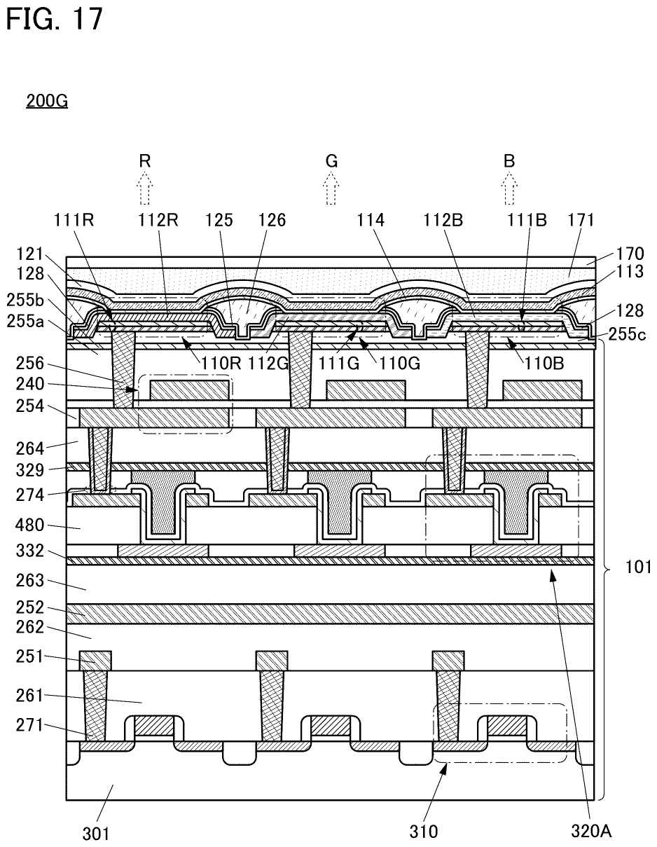

A display panel 200G illustrated in FIG. 17 has a structure in which the transistor 320 in the display panel 200F illustrated in FIG. 16 is replaced with a transistor 320A (vertical transistor). Note that the structure in which the transistor 320 is replaced with the transistor 320A can also be employed for the display panel 200D illustrated in FIG. 15.

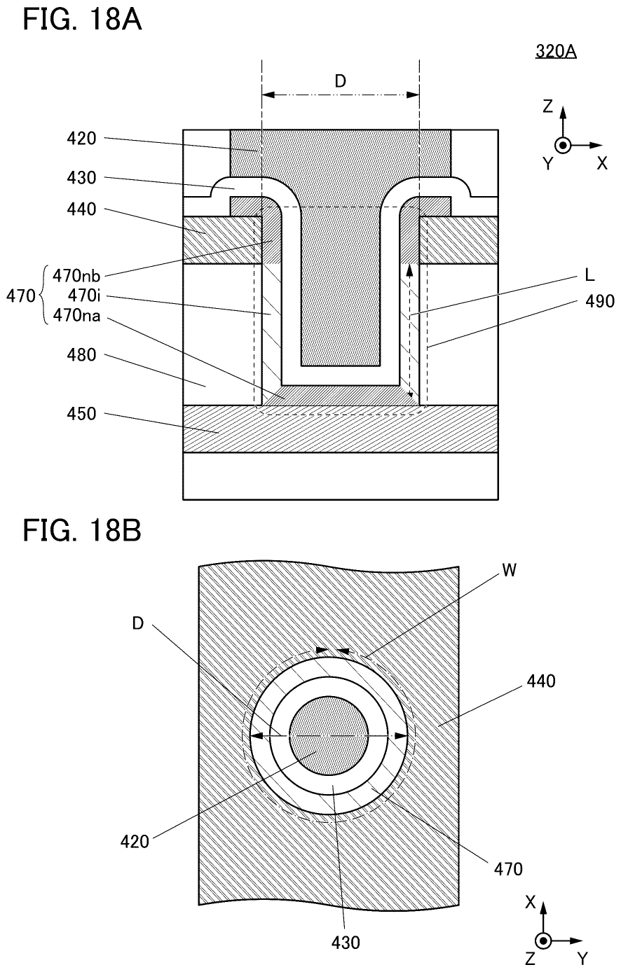

FIG. 18A is a cross-sectional view of the transistor 320A taken along the XZ plane. FIG. 18B is a cross-sectional view taken along the XY plane including a wiring 440.

The transistor 320A includes an oxide semiconductor 470, an insulator 430, and a conductor 420. The oxide semiconductor 470 functions as a semiconductor layer, the insulator 430 functions as a gate insulator, and the conductor 420 functions as a gate electrode. The wiring 450 includes a region functioning as one of the source electrode and the drain electrode of the transistor 320A. The wiring 440 includes a region functioning as the other of the source electrode and the drain electrode of the transistor 320A.

An opening portion 490 penetrating through the wiring 440 and an insulator 480 and reaching the wiring 450 is provided. The opening portion 490 has a columnar shape with a substantially circular top surface. With such a structure, the memory cell can be miniaturized or highly integrated. Note that the side surface of the opening portion 490 is preferably perpendicular to the top surface of the wiring 450.

At least part of the oxide semiconductor 470 is placed in the opening portion 490. Note that the oxide semiconductor 470 includes a region in contact with the top surface of the wiring 450, a region in contact with the side surface of the wiring 440, and a region in contact with the side surface of the insulator 480 in the opening portion 490.

The insulator 430 is placed so as to at least partly cover the opening portion 490. The conductor 420 is placed so as to be at least partly positioned in the opening portion 490. The conductor 420 is preferably provided so as to be embedded in the opening portion 490, and preferably has a substantially circular top surface for a higher integration degree.

As illustrated in FIG. 18A, the oxide semiconductor 470 includes a region 470i, and a region 470na and a region 470nb provided such that the region 470i is interposed therebetween.

The region 470na is a region in contact with the wiring 450 in the oxide semiconductor 470. At least part of the region 470na functions as one of the source region and the drain region of the transistor 320A. The region 470nb is a region in contact with the wiring 440 in the oxide semiconductor 470. At least part of the region 470nb functions as the other of the source region and the drain region of the transistor 320A. As illustrated in FIG. 18B, the wiring 440 is in contact with all the outer circumference of the oxide semiconductor 470. Thus, the other of the source region and the drain region of the transistor 320A can be formed in the entire outer circumference of a portion of the oxide semiconductor 470 that is formed in the same layer as the wiring 440.

The region 470i is a region positioned between the region 470na and the region 470nb in the oxide semiconductor 470. At least part of the region 470i functions as a channel formation region of the transistor 320A. That is, the channel formation region of the transistor 320A is formed in part of the oxide semiconductor 470 that is positioned in a region between the wiring 450 and the wiring 440. In other words, the channel formation region of the transistor 320A is positioned in a region of the oxide semiconductor 470 that is in contact with the insulator 480 or a region in the vicinity thereof.

The channel length of the transistor 320A is the distance between the source region and the drain region. In other words, the channel length of the transistor 320A is determined by the thickness of the insulator 480 over the wiring 450. In FIG. 18A, a channel length L of the transistor 320A is indicated by a dashed double-headed arrow. In the cross-sectional view, the channel length L is a distance between an end portion of a region where the oxide semiconductor 470 is in contact with the wiring 450 and an end portion of a region where the oxide semiconductor 470 is in contact with the wiring 440. That is, the channel length L corresponds to the length of the side surface of the insulator 480 on the opening portion 490 side in the cross-sectional view.

In a conventional transistor, the channel length is determined by the light exposure limit of photolithography; however, in the present invention, the channel length can be determined by the thickness of the insulator 480. Thus, the transistor 320A can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). In that case, the transistor 320A can have a higher on-state current.

In addition, as described above, the channel formation region, the source region, and the drain region can be formed in the opening portion 490. Thus, the occupation area of the transistor 320A can be reduced as compared with a conventional transistor in which a channel formation region, a source region, and a drain region are provided separately on the XY plane. Accordingly, the pixel density of the display apparatus can be increased.

Such a transistor including the channel formation region along the side surface of the insulator 480 in the opening portion 490 is also referred to as a vertical transistor.

Also in the XY plane including the channel formation region of the oxide semiconductor 470, the oxide semiconductor 470, the insulator 430, and the conductor 420 are provided concentrically as in FIG. 18B. Thus, the side surface of the conductor 420 provided at the center faces the side surface of the oxide semiconductor 470 with the insulator 430 therebetween. That is, in the top view, all the circumference of the oxide semiconductor 470 serves as the channel formation region. In this case, for example, the channel width of the transistor 320A is determined by the length of the outer circumference of the oxide semiconductor 470. In other words, the channel width of the transistor 320A is determined by the maximum width of the opening portion 490 (the maximum diameter in the case where the opening portion 490 is circular in the top view). In FIG. 18A and FIG. 18B, a maximum width D of the opening portion 490 is indicated by a dashed double-dotted double-headed arrow. In FIG. 18B, a channel width W of the transistor 320A is indicated by a dashed-dotted double-headed arrow. By increasing the maximum width D of the opening portion 490, the channel width per unit area can be increased and the on-state current can be increased.

In the case where the opening portion 490 is formed by a photolithography method, the maximum width D of the opening portion 490 is determined by the light exposure limit of photolithography. In addition, the maximum width D of the opening portion 490 is determined by the thicknesses of the oxide semiconductor 470, the insulator 430, and the conductor 420 provided in the opening portion 490. The maximum width D of the opening portion 490 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 490 is circular in the top view, the maximum width D of the opening portion 490 corresponds to the diameter of the opening portion 490, and the channel width W can be calculated to be “D×π”.

In the storage device of one embodiment of the present invention, the channel length L of the transistor 320A is preferably smaller than at least the channel width W of the transistor 320A. The channel length L of the transistor 320A in one embodiment of the present invention is greater than or equal to 0.1 times and less than or equal to 0.99 times, preferably greater than or equal to 0.5 times and less than or equal to 0.8 times the channel width W of the transistor 320A. This structure enables a transistor with favorable electrical characteristics and high reliability.

In the case where the opening portion 490 is formed to be circular in the top view, the oxide semiconductor 470, the insulator 430, and the conductor 420 are formed concentrically. This makes the distance between the conductor 420 and the oxide semiconductor 470 substantially equal, so that a gate electric field can be substantially uniformly applied to the oxide semiconductor 470.

It is preferable that the channel formation region of the transistor including an oxide semiconductor in the semiconductor layer contain fewer oxygen vacancies or have a lower concentration of an impurity such as hydrogen, nitrogen, or a metal element than the source region and the drain region. For example, the concentration of aluminum in the channel formation region of the oxide semiconductor is preferably lower than or equal to 1×10²² atoms/cm³, further preferably lower than or equal to 1×10²¹atoms/cm³, still further preferably lower than or equal to 1×10²⁰atoms/cm³, yet further preferably lower than or equal to 5×10¹⁹atoms/cm³, yet still further preferably lower than or equal to 1×10¹⁹atoms/cm³, yet still further preferably lower than or equal to 5×10¹⁸atoms/cm³, yet still further preferably lower than or equal to 1×10¹⁸atoms/cm³.

In some cases, hydrogen in the vicinity of an oxygen vacancy forms a defect that is an oxygen vacancy into which hydrogen has entered (hereinafter sometimes referred to as VoH), which generates an electron serving as a carrier. Therefore, it is preferable that VoH be also reduced in the channel formation region. Thus, the channel formation region of the transistor is a high-resistance region having a low carrier concentration. Thus, the channel formation region of the transistor can be regarded as being i-type (intrinsic) or substantially i-type.

The source region and the drain region of the transistor including an oxide semiconductor in the semiconductor layer include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the transistor are n-type regions that have a higher carrier concentration and a lower resistance than the channel formation region.

Although the opening portion 490 is provided so that the side surface of the opening portion 490 is perpendicular to the top surface of the wiring 450 in FIG. 18A and the like, the present invention is not limited thereto. For example, the side surface of the opening portion 490 may have a tapered shape.

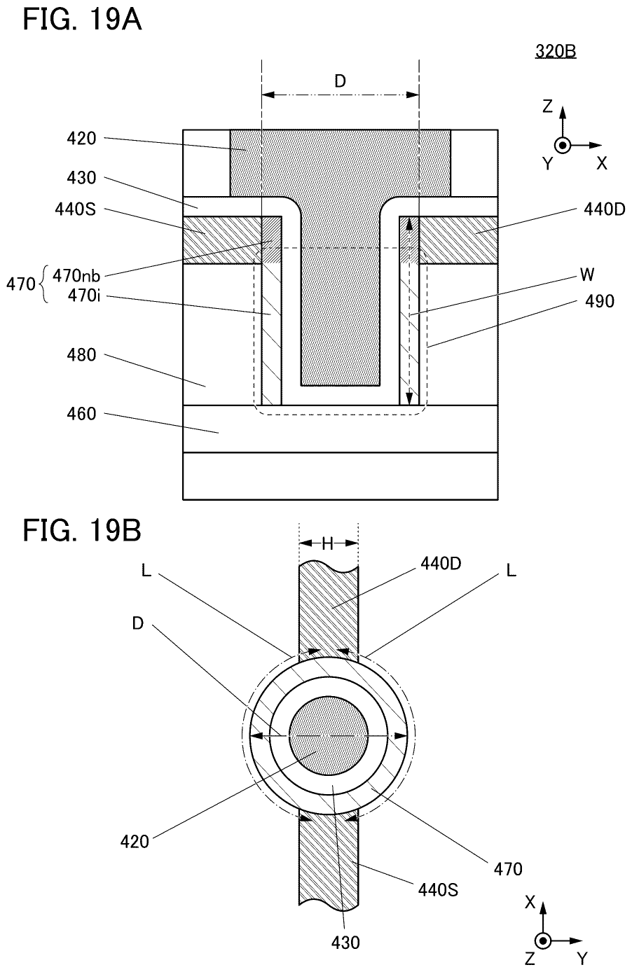

FIG. 19A is a cross-sectional view taken along the XZ plane of a transistor 320B, which is a vertical transistor having a structure different from that in FIG. 18. FIG. 19B is a cross-sectional view taken along the XY plane.

The transistor 320B is different from the transistor 320A mainly in not including the wiring 450, being provided over an insulator 460, including a wiring 440S and a wiring 440D instead of the wiring 440, and the shape of the oxide semiconductor 470. The wiring 440S has a function of a source electrode, and the wiring 440D has a function of a drain electrode.

The oxide semiconductor 470 has a ring shape. Specifically, the oxide semiconductor 470 includes a region in contact with the side surface of the wiring 440S, a region in contact with the side surface of the wiring 440D, and a region in contact with the side surface of the insulator 480 in the opening portion 490. Here, the oxide semiconductor 470 is in contact with neither of the top surfaces of the wiring 440S and the wiring 440D. The oxide semiconductor 470 having such a shape can be formed by processing by anisotropic etching, for example.

As illustrated in FIG. 19B, a width H of each of the wiring 440S and the wiring 440D is smaller than the maximum width D of the opening portion 490. In that case, the circumferential direction of the opening portion 490 corresponds to the channel length direction of the transistor 320B. Here, since the oxide semiconductor 470 has a ring shape, there are two kinds of current paths (i.e., channels) from the wiring 440S to the wiring 440D. Note that the oxide semiconductor 470 does not necessarily have a circular shape and may be in contact with both the wiring 440S and the wiring 440D.

The channel length can be controlled by the shape and size of the opening portion 490. For example, in the case where the channel length is desired to be large, the perimeter of the opening portion 490 is set long. Although this embodiment describes the example where the opening portion 490 has a circular shape in the plan view, the present invention is not limited thereto. For example, the opening portion 490 can have an elliptical shape or a quadrangular shape with rounded corners besides the circular shape in the plan view. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the channel width can be increased. Alternatively, an elliptical shape, a polygonal shape with rounded corners, a closed curve in which a straight line and a curve are combined, or the like can be employed. In that case, the maximum width of the opening portion 490 is calculated as appropriate in accordance with the shape of the uppermost portion of the opening portion 490. For example, in the case where the opening portion is square or rectangular in the plan view, the maximum width of the opening portion 490 may be the length of a diagonal line of the uppermost portion of the opening portion 490.

As illustrated in FIG. 19A, the height of the oxide semiconductor 470 corresponds to the channel width W of the transistor 320B. Thus, the channel width W of the transistor 320B can be controlled by the thickness of the insulator 480. Thus, the transistor 320B can have an extremely small channel width less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm).

The transistor 320A can have an extremely small channel length and a large channel width, and thus can achieve a high on-state current. Meanwhile, the transistor 320B can have an extremely small channel width and a large channel length, and thus can achieve an appropriate on-state current and easy design. The transistor 320A and the transistor 320B can be separately formed over the same substrate while sharing some of the fabrication steps. For example, in a display apparatus, the transistor 320B can be used as a driving transistor for controlling current flowing through the light-emitting element, and the transistor 320A can be used as a transistor functioning as a switch.

At least part of this embodiment can be implemented in combination with the other embodiments and the example described in this specification as appropriate.

### REFERENCE NUMERALS

10: frame, 11: metal plate, 12: projected portion, 13: holding tool, 20: housing, 21: optical device, 22: depressed portion, 23: electromagnet, 24: first surface, 30: multi-joint arm, 32: pivot, 33: bush, 34: shaft, 35: wire, 36: balancer, 37: control unit, 38: cable, 50: ceiling, 60: display unit, 61: display panel, 62: linear polarizing plate, 63: retardation plate, 71: half mirror, 72: lens, 73: retardation plate, 74: reflective polarizing plate, 75: lens, 80: pixel, 81: subpixel, 84: pixel array, 85: circuit, 86: circuit, 87: layer, 88: layer, 89: layer, 100a: display panel, 100b: display panel, 100: display panel, 101: substrate, 110a: light-emitting element, 110B: light-emitting element, 110b: light-emitting element, 110c: light-emitting element, 110G: light-emitting element, 110R: light-emitting element, 110W: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112W: organic layer, 112: organic layer, 113: common electrode, 114: common layer, 115B: conductive layer, 115G: conductive layer, 115R: conductive layer, 116B: coloring layer, 116G: coloring layer, 116R: coloring layer, 121: protective layer, 122: insulating layer, 123: insulating layer, 124a: pixel, 124b: pixel, 125: insulating layer, 126: resin layer, 128: layer, 140: connection portion, 150: pixel, 170: substrate, 171: adhesive layer, 200A: display panel, 200B: display panel, 200C: display panel, 200D: display panel, 200F: display panel, 200G: display panel, 240: capacitor, 241: conductive layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 420: conductor, 430: insulator, 440: wiring, 440D: wiring, 440S: wiring, 450: wiring, 460: insulator, 470i: region, 470na: region, 470nb: region, 470: oxide semiconductor, 480: insulator, 490: opening portion

1. An electronic device of a goggles type, comprising:
a frame and a housing,
wherein the housing comprises a display panel and an optical device inside,
wherein an electromagnet is provided on a first surface of the housing,
wherein the frame comprises a first surface worn on a user's head and a second surface opposite the first surface of the frame, the second surface having a metal plate thereon,
wherein the metal plate is frame-shaped, and
wherein the electromagnet is configured to attract the metal plate when energized, thereby fixing the first surface of the housing and a surface of the metal plate so as to face each other.

2. The electronic device according to claim 1,
wherein the surface of the metal plate comprises a projected portion,
wherein the first surface of the housing comprises a depressed portion, and
wherein the frame and the housing are aligned by matching the projected portion and the depressed portion.

3. The electronic device according to claim 1,
wherein the surface of the metal plate has a convex surface, and
wherein the first surface of the housing has a concave surface.

4. The electronic device according to claim 1,
wherein the surface of the metal plate and the first surface of the housing each have a flat surface.

5. The electronic device according to claim 1,
wherein an assisting tool is connected to the housing to reduce a weight of the housing on the user.

6. The electronic device according to claim 5,
wherein the assisting tool is composed of one or more selected from a multi-joint arm, a slide mechanism, and a balancer.

7. The electronic device according to claim 1,
wherein the display panel comprises an organic EL element.

8. The electronic device according to claim 1,
wherein the optical device comprises a half mirror, a lens, a retardation plate, and a reflective polarizing plate.

9. An electronic device of a goggles type, comprising:
a frame and a housing,
wherein the housing comprises a display panel and an optical device,
wherein an electromagnet is provided on a first surface of the housing,
wherein the frame comprises a first surface worn on a user's head and a second surface opposite the first surface of the frame, the second surface having a metal plate thereon,
wherein the electromagnet is configured to attract the metal plate to fix the first surface of the housing and a surface of the metal plate so as to face each other,
wherein an assisting tool is connected to the housing to reduce a weight of the housing on the user, and
wherein the housing is configured to be attached and detached to the frame without the user's hands by energizing and deenergizing the electromagnet.

10. The electronic device according to claim 9,
wherein the surface of the metal plate comprises a projected portion,
wherein the first surface of the housing comprises a depressed portion, and
wherein the frame and the housing are aligned by matching the projected portion and the depressed portion.

11. The electronic device according to claim 9,
wherein the surface of the metal plate has a convex surface, and
wherein the first surface of the housing has a concave surface.

12. The electronic device according to claim 9,
wherein the surface of the metal plate and the first surface of the housing each have a flat surface.

13. The electronic device according to claim 9,
wherein the assisting tool comprises one or more selected from a multi-joint arm, a slide mechanism, and a balancer.

14. The electronic device according to claim 9,
wherein the display panel comprises an organic EL element.

15. The electronic device according to claim 9,
wherein the optical device comprises a half mirror, a lens, a retardation plate, and a reflective polarizing plate.

16. The electronic device according to claim 9,
wherein the electromagnet is configured to be energized and deenergized using a gaze sensor provided in the housing.

17. The electronic device according to claim 9,
wherein the electromagnet is configured to be energized and deenergized using a speech recognition part provided in the housing.
